(19) United States
(12) Patent Application Publication
(10) Pub. No.: US 2026/0221203 A1
(43) Pub. Date: Jul. 30, 2026

(54) SEMICONDUCTOR MEMORY DEVICE AND METHOD FOR STORING DATA IN SEMICONDUCTOR MEMORY DEVICE

(71) Applicant: Kioxia Corporation, Tokyo (JP)

(72) Inventors: Tatsuo OGURA, Yokkaichi (JP); Shunichi SENO, Yokkaichi (JP); Fumitaka ARAI, Yokkaichi (JP)

(73) Assignee: Kioxia Corporation, Tokyo (JP)

(21) Appl. No.: 19/235,728

(22) Filed: Jun. 12, 2025

(30) Foreign Application Priority Data
Jan. 24, 2025 (JP) 2025-010680

(51) Int. Cl. G11C 16/34; G11C 16/08; G11C 16/10

(52) U.S. Cl. CPC G11C 16/3404; G11C 16/08; G11C 16/102

(57) ABSTRACT

According to an embodiment, the circuit included in the semiconductor memory device changes the threshold voltage of each of the second plurality of memory cells out of the first plurality of memory cells by a uniform amount. The circuit then identifies which of two or more voltage ranges delimited by the one or more read levels the threshold voltage of each of the second plurality of memory cells is in. The circuit executes, to a third plurality of memory cells out of the second plurality of memory cells, an operation of selecting a plurality of memory cells included in one group and applying one program pulse of a voltage according to a voltage range corresponding to one group to the first word line for each group of memory cells sharing a common voltage range in which a threshold voltage is present out of the two or more voltage ranges.

### CROSS-REFERENCE TO RELATED APPLICATIONS

This application is based upon and claims the benefit of Japanese Patent Application No. 2025-010680,filed on Jan. 24, 2025; the entire contents of which are incorporated herein by reference.

### FIELD

Embodiments described herein relate generally to a semiconductor memory device and a method for storing data in a semiconductor memory device.

### BACKGROUND

As a semiconductor memory device, NAND-type flash memories are known, which allow multiple bits of data to be stored per memory cell.

### BRIEF DESCRIPTION OF THE DRAWINGS

FIG. 1 is a diagram illustrating a configuration example of a memory system according to the first embodiment;

FIG. 2 is a diagram illustrating an example of the configuration of a memory chip according to the first embodiment;

FIG. 3 is a diagram illustrating the circuit configuration of the block according to the first embodiment;

FIG. 4 is a diagram for explaining an example of data coding according to the first embodiment;

FIG. 5 is a diagram illustrating the potential changes of each wiring during the program operation according to the first embodiment;

FIG. 6 is a circuit diagram illustrating the states of the NAND string during the program operation according to the first embodiment;

FIG. 7 is a diagram illustrating the potential changes of each wiring when a voltage at one read level is applied according to the first embodiment;

FIG. 8 is a diagram for explaining the two-stage write operation according to the first embodiment;

FIG. 9 is a schematic diagram for explaining the first write operation according to the first embodiment;

FIG. 10 is a schematic diagram for explaining the voltage of the program pulse applied to the selected word line in the first write operation according to the first embodiment;

FIG. 11 is a diagram for explaining the Pass Write method according to the first embodiment;

FIG. 12 is a diagram for explaining the Foggy & Fine method according to the first embodiment;

FIG. 13 is a flow chart illustrating an example of a write operation in the memory chip CP according to the first embodiment;

FIG. 14 is a diagram illustrating the potential changes of each wiring during QPW operation according to the second embodiment; and

FIG. 15 is a schematic diagram for explaining the voltage of the program pulse applied to the selected word line in the first write operation according to the second embodiment.

### DETAILED DESCRIPTION

According to this embodiment, the semiconductor memory device includes a first plurality of memory cells and a circuit. A gate of each of the first plurality of memory cells is connected to a first word line. A circuit executes a first operation of setting a threshold voltage of each of the first plurality of memory cells to a first state corresponding to data out of a plurality of first states. In the first operation, the circuit operates as follows. The circuit causes a threshold voltage of each of a second plurality of memory cells out of the first plurality of memory cells to change by a uniform amount by applying a program pulse of a first voltage to the first word line. Then, after applying the program pulse of the first voltage, by executing a read operation using one or more read levels different from each other for the second plurality of memory cells, the circuit identifies which of two or more voltage ranges delimited by the one or more read levels the threshold voltage of each of the second plurality of memory cells is in. The circuit then sets a threshold voltage of a third plurality of memory cells to the second state by executing, to the third plurality of memory cells having a setting destination of the threshold voltage in a second state, which is one of the plurality of first states, out of the second plurality of memory cells, an operation of selecting a plurality of memory cells included in one group and applying one program pulse of a voltage according to a voltage range corresponding to one group to the first word line for each group of memory cells that share a common voltage range in which a threshold voltage is present out of the two or more voltage ranges.

Hereinafter, semiconductor memory devices and methods for storing data in the semiconductor memory device according to embodiments will be described in detail with reference to the attached drawings. It should be noted that these embodiments do not limit the present invention.

### First Embodiment

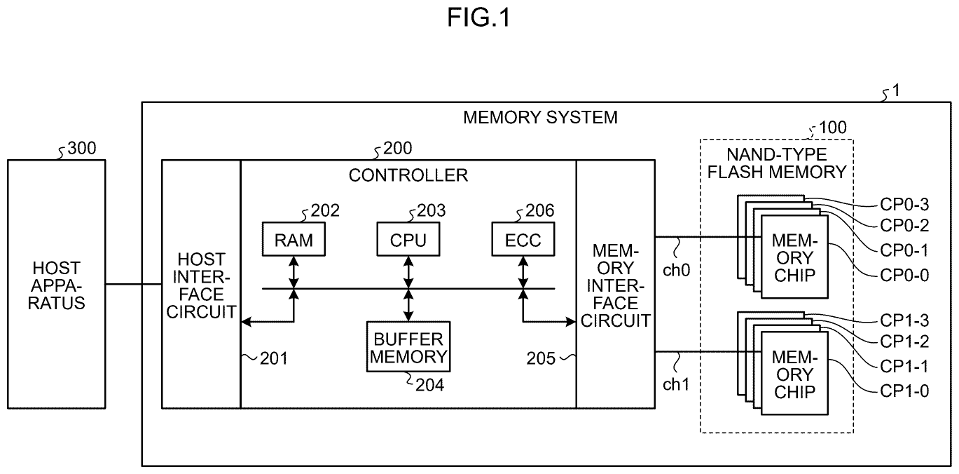

FIG. 1 is a diagram illustrating a configuration example of a memory system according to the first embodiment.

As illustrated in FIG. 1, the memory system 1 is connectable to the host apparatus 300. The host apparatus 300 may be, for example, a server, a personal computer, a mobile type information processing device, or the like. The memory system 1 functions as an external memory device for the host apparatus 300. The host apparatus 300 can issue various requests to the memory system 1. The various requests include write requests and read requests.

The memory system 1 includes a NAND-type flash memory 100 and a controller 200. The NAND-type flash memory 100 includes one or more memory chips CP. It should be noted that each memory chip CP is an example of a semiconductor memory device.

One or more channels are connected to the controller 200, and the controller 200 and the one or more memory chips CP are connected to each other via one or more channels.

Here, the memory system 1 includes memory chips CP0-0, CP0-1, CP0-2, CP0-3, CP1-0, CP1-1, CP1-2, and CP1-3 as one or more memory chips CP, and includes channels ch0 and ch1 as one or more channels. Memory chips CP0-0, CP0-1, CP0-2, and CP0-3 are connected to the controller 200 via channel ch0. Memory chips CP1-0, CP1-1, CP1-2, and CP1-3 are connected to the controller 200 via channel ch1. It should be noted that the number of memory chips CP included in the memory system 1 is not limited to eight. The number of channels connected to the controller 200 is not limited to two. In addition, the connection relationship between the controller 200 and one or more memory chips CP is not limited to the relationship described above.

Each memory chip CP includes a plurality of memory cell transistors, and data can be stored nonvolatilely.

The controller 200 includes a host interface circuit 201, a random access memory (RAM) 202, a central processing unit (CPU) 203, a buffer memory 204, a memory interface circuit 205, and an error-correcting code (ECC) circuit 206.

The controller 200 may be configured, for example, as a System-On-a-Chip (SoC). The controller 200 may be made up of a plurality of chips. The controller 200 may include a field-programmable gate array (FPGA) or an application specific integrated circuit (ASIC) instead of the CPU 203. That is, the controller 200 may be made of software, hardware, or a combination thereof. The RAM 202 may be located outside the controller 200.

The host interface circuit 201 is connected to the host apparatus 300 via a bus that conforms to, for example, the Serial Advanced Technology Attachment (SATA) standard, the Serial Attached SCSI (SAS) standard, the Peripheral Components Interconnect (PCI) Express (trademark), or the like. The host interface circuit 201 manages communication between the controller 200 and the host apparatus 300. It should be noted that the standards for which the bus that connects the host interface circuit 201 and the host apparatus 300 are conformed are not limited thereto.

The memory interface circuit 205 is connected to eight memory chips CP via two channels, and manages communication between the controller 200 and each memory chip CP.

The CPU 203 controls the operation of the controller 200.

The RAM 202 is used as a work area for the CPU 203. The buffer memory 204 temporarily stores data transmitted to the memory chip CP and data received from the memory chip CP. The RAM 202 and the buffer memory 204 may be made up of, for example, a dynamic random access memory (DRAM), a static random access memory (SRAM), or a combination thereof. It should be noted that the types of memories that make up the RAM 202 and the buffer memory 204 are not limited thereto.

The ECC circuit 206 executes error correction coding on the data written to the NAND-type flash memory 100. The ECC circuit 206 executes error correction on the data read from the NAND-type flash memory 100.

It should be noted that the ECC circuit 206 may be included in the memory interface circuit 205. Some or all of the functions of the ECC circuit 206 may be implemented by the CPU 203.

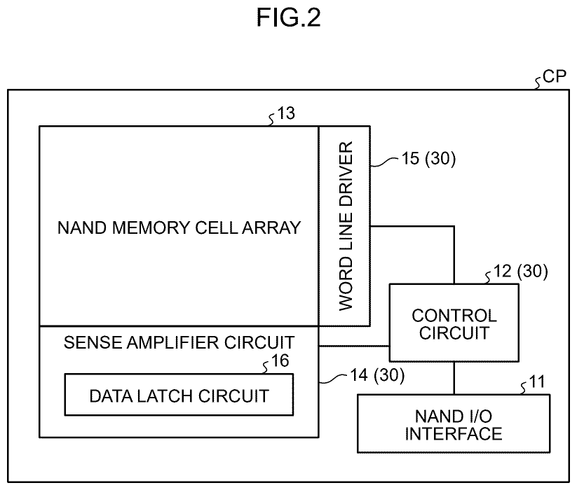

FIG. 2 is a diagram illustrating an example of the configuration of the memory chip CP according to the first embodiment. It should be noted that a plurality of memory chips CP that makes up the NAND flash memory 100 have a common configuration.

The memory chip CP includes a NAND I/O interface 11, a control circuit 12, a NAND memory cell array 13, a sense amplifier circuit 14, and a word line driver 15. The sense amplifier circuit 14 includes a data latch circuit 16. The control circuit 12, the sense amplifier circuit 14 and the word line driver 15 makes up the access circuit 30. The access circuit 30 is an example of a circuit.

The NAND I/O interface 11 receives various signals from the controller 200. The various signals include commands, addresses, or data.

The control circuit 12 controls the operation of the memory chip CP in response to a signal received by the NAND I/O interface 11. The control circuit 12 controls the word line driver 15 and the sense amplifier circuit 14 to execute write operations, read operations, erase operations, and the like. The write operation is an operation for storing data in the NAND memory cell array 13. The read operation is an operation in which data stored in the NAND memory cell array 13 is obtained from the NAND memory cell array 13. The erase operation is an operation in which data stored in the NAND memory cell array 13 is erased from the NAND memory cell array 13.

When a write command is input, the control circuit 12 controls the sense amplifier circuit 14 and the word line driver 15 so that the data inputted along with the write command is stored at a designated address on the NAND memory cell array 13. In addition, when a read command is input, the control circuit 12 controls the sense amplifier circuit 14 and the word line driver 15 so as to obtain data from the designated address on the NAND memory cell array 13.

For example, the control circuit 12 controls the voltages applied to the plurality of word lines WL by the word line driver 15 and the voltages (bit line voltages) applied to the plurality of bit lines BL by the sense amplifier circuit 14 in order to store data in the memory cell transistors MT included in the NAND memory cell array 13.

The sense amplifier circuit 14 is configured to allow voltages (or currents) to be applied independently to the plurality of bit lines BL, and voltages (or currents) of the plurality of bit lines BL to be detected independently.

It should be noted that the sense amplifier circuit 14 uses a data latch circuit 16 during write operation. The details of how the data latch circuit 16 are used will be described later.

The word line driver 15 is configured to allow voltages to be applied independently to a plurality of word lines and a selection gate line.

The NAND memory cell array 13 includes a plurality of blocks BLK. The block BLK is a sub-array that is used as a unit of erasing operations. That is, data written to one block BLK is erased all at once.

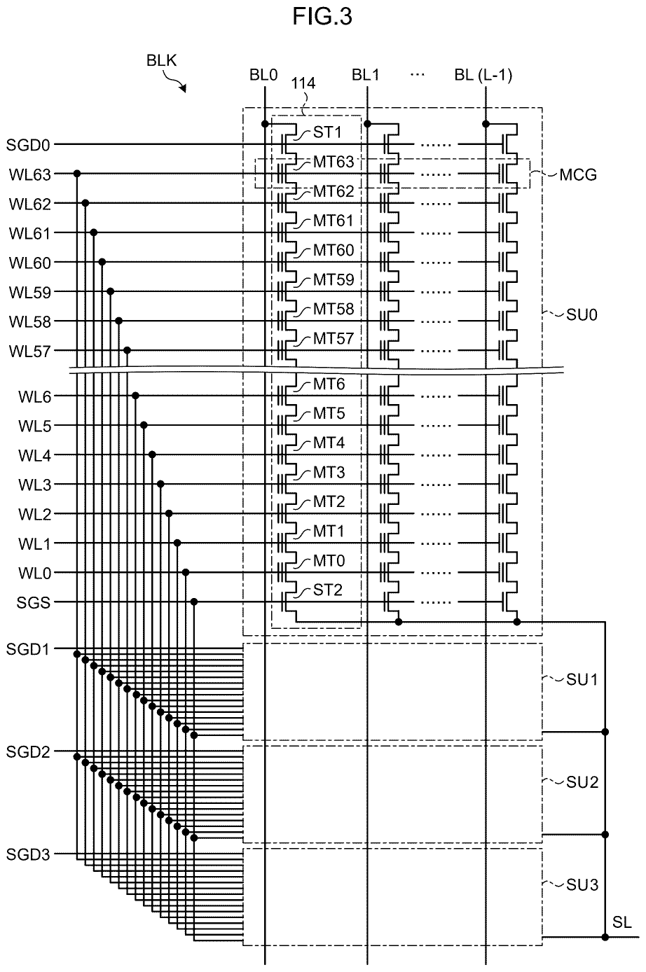

FIG. 3 is a diagram illustrating the circuit configuration of the block BLK according to the first embodiment. It should be noted that each block BLK has the same configuration. The block BLK has, for example, four string units SU0 to SU3. Each string unit SU includes a plurality of NAND strings 114.

Each of the NAND strings 114 includes, for example, 64 memory cell transistors MT (MT0 to MT63) and selection transistors ST1 and ST2. The memory cell transistor MT includes a control gate and a charge accumulation layer, and holds data nonvolatile. The 64 memory cell transistors MT (MT0 to MT63) are connected in series between the source of the selection transistor ST1 and the drain of the selection transistor ST2. It should be noted that the memory cell transistor MT may be of a metal oxide nitride oxide silicon (MONOS) type in which an insulating film is used as the charge accumulation layer, or of a floating gate (FG) type in which an electrically conductive film is used as the charge accumulation layer. Furthermore, the number of memory cell transistors MT in the NAND string 114 is not limited to 64.

The gates of the selection transistors ST1 in the string units SU0 to SU3 are connected to the selection gate lines SGD0 to SGD3, respectively. In contrast, the gates of the selection transistors ST2 in the string units SU0 to SU3 are connected in common, for example, to the selection gate line SGS. The gates of the selection transistors ST2 in the string units SU0 to SU3 may be connected to different selection gate lines SGS0 to SGS3 (not illustrated) for each string unit SU. The control gates of the memory cell transistors MT0 to MT13 in the same block BLK are connected in common to the word lines WL0 to WL13, respectively.

The drains of the selection transistors ST1 of the NAND strings 114 in the string unit SU are connected to different bit lines BL (BL0 to BL(L-1), where L is a natural number of two or more). In addition, the bit line BL commonly connects one NAND string 114 in each string unit SU between the plurality of blocks BLK. Furthermore, the sources of the selection transistors ST2 are commonly connected to the source line SL.

That is, the string unit SU is a set of NAND strings 114 connected to different bit lines BL and connected to the same selection gate line SGD. In addition, the block BLK is a set of a plurality of string units SU that share the word lines WL. The NAND memory cell array 13 is a set of a plurality of blocks BLK that share the bit lines BL.

As mentioned above, the erasing operation of data for the NAND memory cell array 13 is executed in block BLK units.

In addition, write operations to the NAND memory cell array 13 and read operations from the NAND memory cell array 13 are executed collectively for memory cell transistors MT connected to one word line WL in one string unit SU. Hereinafter, a group of memory cell transistors MT in which write and read operations are executed collectively will be referred to as a memory cell group MCG. A collection of storage areas for one bit of data stored in each of the memory cell transistors MT included in one memory cell group MCG will be referred to as a page.

Hereafter, the memory cell transistor MT will simply be referred to as a memory cell.

Each memory cell can store n (n≥1) bits of data. When n-bit data is stored in each memory cell, the storage capacity per memory cell group MCG is equal to the size of n pages. A mode where n is 1 is called Single Level Cell (SLC) mode. A mode where n is 2 is called Multi Level Cell (MLC) mode. A mode where n is 3 is called Triple Level Cell (TLC) mode. A mode where n is 4 is called Quad Level Cell (QLC) mode.

The threshold voltage of each memory cell is controlled by the access circuit 30 so as to fall within a certain range. The controllable range of the threshold voltage is divided into a range of n-powers of two, with different n-bit values assigned to each range.

In the first embodiment, a mode in which n is 2 or more is employed. Hereafter, an example in which memory cells are used in TLC mode as an example of a mode in which n is 2 or more will be described. It should be noted that the first embodiment is not limited to systems in which memory cells are used in TLC mode, but is applicable to systems in which memory cells are used in any mode in which n is 2 or more.

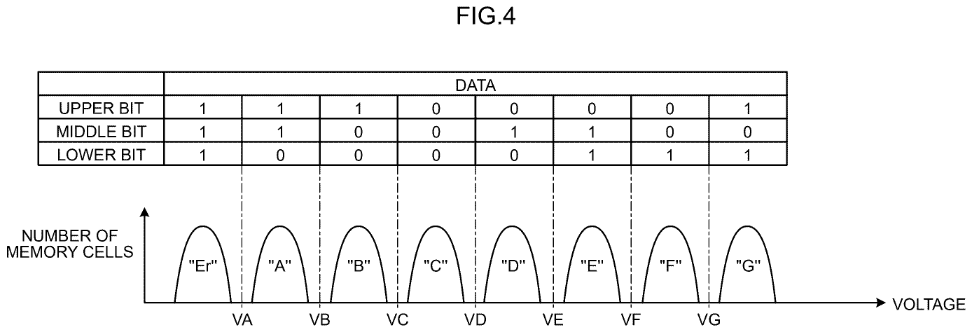

FIG. 4 is a diagram for explaining an example of data coding according to the first embodiment.

As mentioned above, according to TLC mode, 3 bits of data is stored per memory cell. Each bit included in the 3-bit data stored in the memory cell is referred to as an upper bit, a middle bit, and a lower bit, depending on the order in which it is arranged. Of the three pages included in the memory cell group MSG, a page in which the group of upper bits is stored is referred to as an upper page, a page in which the group of middle bits is stored is referred to as a middle page, and a page in which the group of lower bits is stored is referred to as a lower page.

According to TLC mode, the range of possible threshold voltages is divided into eight ranges. These eight ranges will be referred to as the “Er” state, “A” state, “B” state, “C” state, “D” state, “E” state, “F” state, and “G” state in order from the lowest threshold voltage. The threshold voltage of each memory cell is controlled by access circuit 30 so as to belong to any of the “Er” state, “A” state, “B” state, “C” state, “D” state, “E” state, “F” state, and “G” state. As a result, when the number of memory cells versus the threshold voltage is plotted, the memory cells ideally form eight lobe-like distributions that do not overlap each other, each belonging to a different state, as illustrated in the lower part of FIG. 4. In the following, the distribution of memory cells for each state may be simply referred to as the distribution of state.

The eight states correspond to 3 bits of data. The table at the top of FIG. 4 illustrates an example of the correspondence between states and 3-bit data, namely data coding. According to this example, the “Er” state corresponds to “111”, the “A” state corresponds to “110”, the “B” state corresponds to “100”, the “C” state corresponds to “000”, the “D” state corresponds to “010”, the “E” state corresponds to “011”, the “F” state corresponds to “001”, and the “G” state corresponds to “101”. It should be noted that when 3-bit data is written as “abc”, “a” is the upper bit, “b” is the middle bit, and “c” is the lower bit. In this way, each memory cell can store data according to the state to which the threshold voltage belongs. It should be noted that the correspondence between the state and data illustrated in FIG. 4 is an example of data coding. Data coding is not limited to the examples illustrated in this figure.

The threshold voltage is reduced to the “Er” state by an erase operation. In addition, the threshold voltage is maintained in the “Er” state by write operation or increased to any of the “A” state, “B” state, “C” state, “D” state, “E” state, “F” state, and “G” state.

In the write operation, a program operation in which the threshold voltage is increased by injecting electrons into the charge accumulation film (or the threshold voltage is maintained by inhibiting injection) is executed. Hereinafter, the operation for increasing the threshold voltage is referred to as “0” program”, and “0” data is given to the bit line BL that is the target of the “0” program. On the other hand, the operation for maintaining the threshold voltage is referred to as “1” program”, and “1” data is given to the bit line BL that is the target of the “1” program.

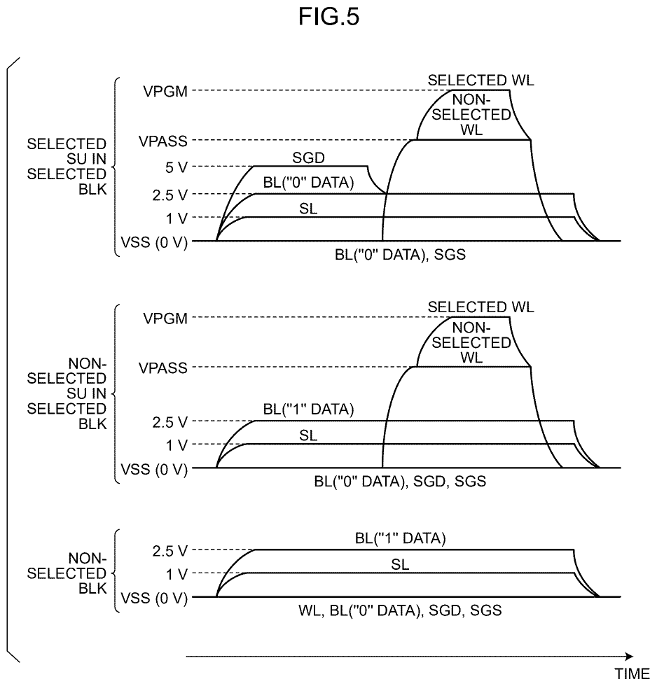

FIG. 5 is a diagram illustrating potential changes of each wiring during the program operation according to the first embodiment. As illustrated in this figure, first, the sense amplifier circuit 14 transfers program data to each bit line BL. A ground voltage Vss (for example, 0 V) is applied to the bit line BL to which the “0” data is given as a “L” level. A write inhibit voltage Vinhibit (for example, 2.5 V) is applied to the bit line BL to which the “1” data is given as an “H” level.

In addition, the word line driver 15 selects any of the blocks BLK and further selects any of the string units SU. Then, for example, 5 V is applied to the select gate line SGD in the selected string unit SU to turn the selection transistor ST1 on. On the other hand, the voltage Vss is applied to the select gate line SGS, thereby causing the select transistor ST2 to be turned off.

Furthermore, the word line driver 15 applies voltages Vss to the select gate lines SGD and SGS of the unselected string unit SU in the selected block BLK and the unselected string unit SU in the unselected block BLK, thereby causing the selection transistors ST1 and ST2 to be turned off.

In addition, the source line SL is set to, for example, 1 V (a potential higher than the potential of the select gate line SGS).

After that, the word line driver 15 sets the potential of the select gate line SGD in the selected string unit SU in the selected block BLK to, for example, 2.5 V. This potential is the voltage that turns on the selection transistor ST1 corresponding to the bit line BL to which “0” data (0 V) is given, but cuts off the selection transistor ST1 corresponding to the bit line BL to which “1” data (2.5 V) is given.

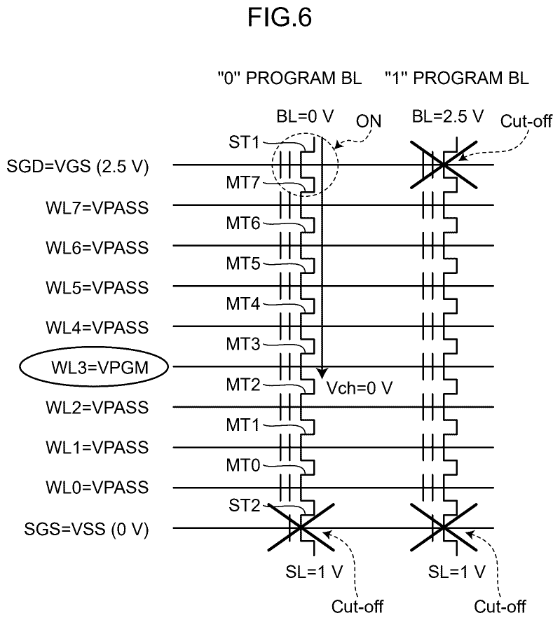

The word line driver 15 selects any of the word lines WL in the selected block BLK, applies a voltage Vpgm to the selected word line, and applies a voltage Vpass_pgm to other unselected word lines. The voltage Vpgm is a high voltage for injecting electrons into the charge accumulation film by the tunneling phenomenon, and Vpgm>Vpass_pgm. The state of the string unit SU at this time is illustrated in FIG. 6. FIG. 6 is a circuit diagram illustrating the state of the NAND string 114 during the program operation according to the first embodiment.

FIG. 6 illustrates two NAND strings corresponding to the bit line BL that is the target of the “0” program and the bit line BL that is the target of the “1” program. In addition, the state in which the word line WL3 is selected is illustrated. It should be noted that in this figure, it is assumed that eight memory cells (MT0 to MT7) are connected to one NAND string 114.

As illustrated in FIG. 6, a voltage Vpgm is applied to the selected word line WL3, and a voltage Vpass_pgm is applied to the unselected word lines WL0 to WL2 and WL4 to WL7.

Then, in the NAND string corresponding to the bit line BL that is the target of the “0” program, the selection transistor ST1 is turned on. For that reason, the channel potential Vch of the memory cell MT3 connected to the selected word line WL3 becomes 0 V. That is, the potential difference between the gate and the channel increases, and as a result, electrons are injected into the charge accumulation film, and the threshold value of the memory cell MT3 is increased.

In the NAND string corresponding to the bit line BL that is the target of the “1” program, the selection transistor ST1 is in the cutoff state. For that reason, the channel of the memory cell MT3 connected to the selected word line WL3 becomes electrically floating, and the channel potential Vch is increased to near the voltage Vpgm due to capacitive coupling with the word line WL and the like. That is, the potential difference between the gate and the channel decreases, and as a result, no electrons are injected into the charge accumulation film, and the threshold value of the memory cell MT3 is maintained.

Hereafter, a memory cell with a threshold voltage set to a certain state due to a program operation may be referred to as a memory cell belonging to that state. In addition, in order to execute a “0” program for a memory cell, an operation in which “0” data is given to the bit line BL connected to the memory cell is referred to as selecting the memory cell.

The explanation will be returned to FIG. 4.

A read level, which is a determination voltage for determining data, is set between two adjacent states. For example, as illustrated in FIG. 4, a read level VA is set between the “Er” state and the “A” state, a read level VB is set between the “A” state and the “B” state, a read level VC is set between the “B” state and the “C” state, a read level VD is set between the “C” state and the “D” state, a read level VE is set between the “D” state and the “E” state, a read level VF is set between the “E” state and the “F” state, and a read level VG is set between the “F” state and the “G” state.

In the read operation, the access circuit 30 sequentially applies voltages of a plurality of read level to the selected word lines to determine for each memory cell whether the memory cell is in a conducting state (in other words, an on state) or a non-conducting state (in other words, an off state) when a voltage of each read level is applied. The access circuit 30 then determines data associated with the state to which the memory cell belongs by logic operations using the determination result obtained for each read level used. That is, data is obtained based on a comparison of the threshold voltage and the read level of each memory cell.

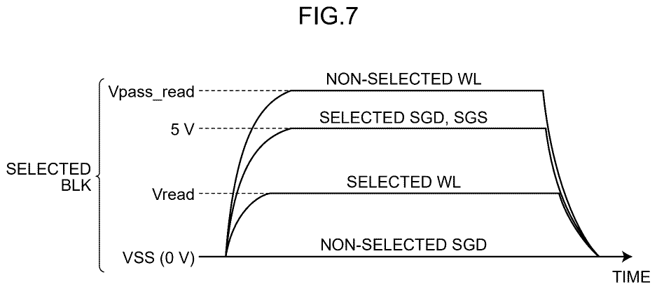

FIG. 7 is a diagram illustrating the potential changes of each wiring when a voltage at one read level is applied according to the first embodiment.

The word line driver 15 selects the block BLK and the string unit SU in which the program operation is executed, and applies, for example, 5 V to the select gate line SGS in the selected block BLK and the select gate line SGD in the selected string unit SU. Accordingly, both the selection transistor ST1 and the selection transistor ST2 are turned on in the NAND string 114 included in the selected string unit SU.

On the other hand, a voltage Vss is applied to the select gate line SGS in the unselected block BLK and to the select gate line SGD in the unselected string unit SU in the selected block BLK, causing the selection transistors ST1 and/or ST2 to be turned off. Accordingly, at least the selection transistor ST1 is turned off in the NAND string included in the unselected string unit SU. In addition, both the selection transistor ST1 and the selection transistor ST2 are turned off in the NAND string 114 included in the non-selected block BLK.

In addition, the word line driver 15 selects any of the word lines WL in the selected block BLK, applies a read level voltage to the selected word line as a voltage Vread, and applies a voltage Vpass_read to other non-selected word lines. The voltage Vpass_read is a voltage for turning on the memory cells MT connected to the unselected word lines regardless of their threshold voltages, and Vpass_read>Vread.

The sense amplifier circuit 14 then charges each bit line BL to the voltage Vbl. The voltage Vbl is greater than the voltage Vsl of the source line, and Vbl>Vsl. Accordingly, in the NAND string included in the selected string unit SU, a current flows (or does not flow) from the bit line BL side to the source line SL side, depending on the threshold voltage of the memory cell MT connected to the selected word line. Based on whether this current flows or not, the sense amplifier circuit 14 determines whether the memory cell is in a conducting or non-conducting state for each memory cell connected to the selected word line.

In the read operation, the access circuit 30 determines the data stored in the memory cell by executing the operations illustrated in FIG. 7 for each of the plurality of read levels.

The threshold voltage of a memory cell can vary due to a variety of factors, including mutual interference between memory cells connected to adjacent bit lines. Therefore, a part on the high voltage side or a part on the low voltage side of the threshold voltage distribution for each state may deviate from the range between two read levels corresponding to the boundary of that state.

If a part on the high voltage side or a part on the low voltage side of the threshold voltage distribution of a state deviates from the range between two read levels corresponding to the boundary of that state, in read operation, erroneous data, that is, errors, are read from the memory cells contained in the part where the threshold voltage deviates from that range. The erroneous data is sent to the controller 200 and corrected by the ECC circuit 206 included in the controller 200.

However, there is a limit to the number of error bits that can be corrected by the ECC circuit 206. Therefore, it is desirable that the threshold voltage of each memory cell be set so as not to deviate as much as possible from the range corresponding to the target state during a write operation.

In order to prevent the threshold voltage of each memory cell from being deviated from the range corresponding to the target state as much as possible, the memory chip CP executes a write operation by dividing it into a plurality of stages. In the first embodiment, the memory chip CP executes a two-stage write operation. The first stage write operation of the two-stage write operation is referred to as a first write operation, and the second stage write operation of the two-stage write operation is referred to as a second write operation.

In the first write operation, data of all bits (for example, 3 bits in the case of the TLC method) is roughly written to a memory cell. That is, the threshold voltage of the memory cell is set roughly according to the data of all bits. Thereafter, in the second write operation, data of all bits is precisely rewritten to the memory cell. That is, the threshold voltage of the memory cell is precisely set in accordance with the data of all bits.

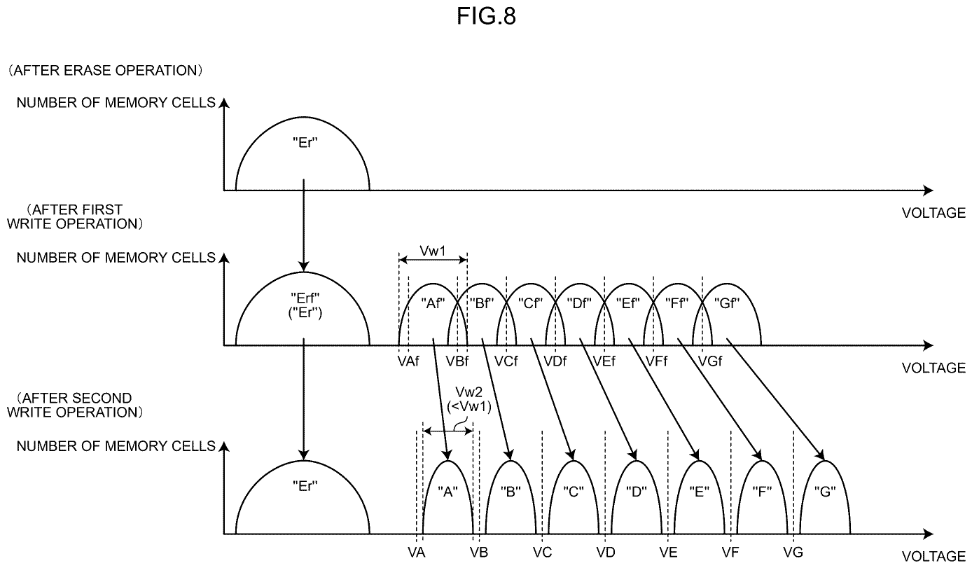

FIG. 8 is a diagram for explaining the two-stage write operation according to the first embodiment. FIG. 8 illustrates three graphs illustrating changes in the distribution of the threshold voltage of memory cells making up one memory cell group MCG. In each graph, the horizontal axis indicates voltage, and the vertical axis indicates number of memory cells. Here, the range from one voltage VX to another voltage VY is referred to as the range VX-VY.

In the block BLK after the erase operation, the threshold voltages of all the memory cells are in the state “Er”.

A first write operation is executed on the memory cell group MCG in a state after the erase operation. In the first write operation, the threshold voltage of each memory cell is roughly set to be as close as possible to the target state out of the eight states “Er” to “G”.

More specifically, a range VAf-VBf obtained by slightly shifting the range VA-VB to the low voltage side, a range VBf-VCf obtained by slightly shifting the range VB-VC to the low voltage side, a range VCf-VDf obtained by slightly shifting the range VC-VC to the low voltage side, a range VDf-VEf obtained by slightly shifting the range VD-VC to the low voltage side, a range VEf-VFf obtained by slightly shifting the range VE-VC to the low voltage side, a range VFf-VGf obtained by slightly shifting the range VF-VG to the low voltage side, and a range larger than the voltage BGf are provided. The threshold voltage of the memory cell for which the target state is the state “Er” is maintained, the threshold voltage of the memory cell for which the target state is the state “A” is set within the range VAf-VBf, the threshold voltage of the memory cell for which the target state is the state “B” is set within the range VBf-VCf, the threshold voltage of the memory cell for which the target state is the state “C” is set within the range VCf-VDf, the threshold voltage of the memory cell for which the target state is the state “D” is set within the range VDf-VEf, the threshold voltage of the memory cell for which the target state is the state “E” is set within the range VEf-VFf, the threshold voltage of the memory cell for which the target state is the state “F” is set within the range VFf-VGf, and the threshold voltage of the memory cell for which the target state is the state “G” is set to a voltage slightly larger than the voltage VGf.

As a result, after the first write operation, a lobe-like distribution is formed in each of a range smaller than the voltage VAf, a range of VAf-VBf, a range of VBf-VCf, a range of VCf-VDf, a range of VDf-VEf, a range of VEf-VFf, a range of VFf-VGf, and a range larger than the voltage BGf. A range smaller than the voltage VAf is referred to as state “Erf”, a range VAf-VBf is referred to as state “Af”, a range VBf-VCf is referred to as state “Bf”, a range VCf-VDf is referred to as state “Cf”, a range VDf-VEf is referred to as state “Df”, a range VEf-VFf is referred to as state “Ef”, a range VFf-VGf is expressed as state “Ff”, and a range larger than the voltage BGf is referred to as state “Gf”.

The states “Erf”, “Af”, “Bf”, “Cf”, “Df”, “Ef”, “Ff”, and “Gf” that are the targets of the first write operation are denoted as intermediate target states. The states “Er”, “A”, “B”, “C”, “D”, “E”, “E”, “F”, and “G” that are the targets of the second write are denoted as final target states. It should be noted that in the first write operation, the threshold voltage of the memory cell in which the intermediate target state is the state “Erf” is maintained at the same voltage. Therefore, the state “Erf” is equal to the state “Er”.

In the first write operation, the threshold voltage of each memory cell is set roughly compared to the second write operation. Therefore, the threshold voltage distributions for the states “Af”, “Bf”, “Cf”, “Df”, “Ef”, “Ff”, and “Gf” can deviate from the corresponding range.

In the second write operation, the program operation and the read operation for checking whether the threshold voltage of the memory cell has reached the final target state are repeated alternately. The read operation for checking whether the threshold voltage of the memory cell has reached the final target state is also referred to as a verify operation. In the verify operation, the operations described in FIG. 7 are executed, for example. In the program operation, regardless of which state the final target state is, all memory cells for which the threshold voltage has not yet reached the final target state are selected and a program pulse is applied to the word line WL. Furthermore, the voltage Vpgm of the program pulse is controlled so that the amount of change in the threshold voltage per application of the program pulse is finer. This allows for control so that the lobe-like distribution for each final target state does not deviate as much as possible from the boundary of the final target state. Therefore, the voltage width (for example, Vw2 in FIG. 8) of the threshold voltage distribution for each state except for the state “Erf” of all the final target states is set narrower than the voltage width (for example, Vw1 in FIG. 8) of the threshold voltage distribution for each state except for the state “Er” of all the intermediate target states.

A technique compared with the first embodiment will be described. The technique compared with the first embodiment is referred to as a comparative example.

According to the comparative example, the program operation and the verify operation are executed repeatedly also in the first write operation, just like the second write operation. The voltage Vpgm of the program pulse is controlled so that the amount of change in the threshold voltage per program operation is greater than the amount of change in the second write operation. This allows the threshold voltage of each memory cell to be roughly set to the intermediate target state compared to the second write operation.

In addition, in the comparative example, in the program operation, regardless of which state the intermediate target state is, all memory cells for which the threshold voltage has not yet reached the intermediate target state are selected, and a program pulse is applied to the word line WL. Therefore, for a memory cell for which the intermediate target state is the state “Gf”, there is a large number of required program operations.

Thus, according to the comparative example, verify operations are required for each program operation, and the number of program operations required is large. Therefore, according to the comparative example, the first write operation takes a large amount of time.

In the first embodiment, in order to shorten the time required for the first write operation, the voltage of the program pulse is made different for each memory cell in the first write operation, depending on the characteristics of the memory cell and the intermediate target state (which can also be referred to as the final target).

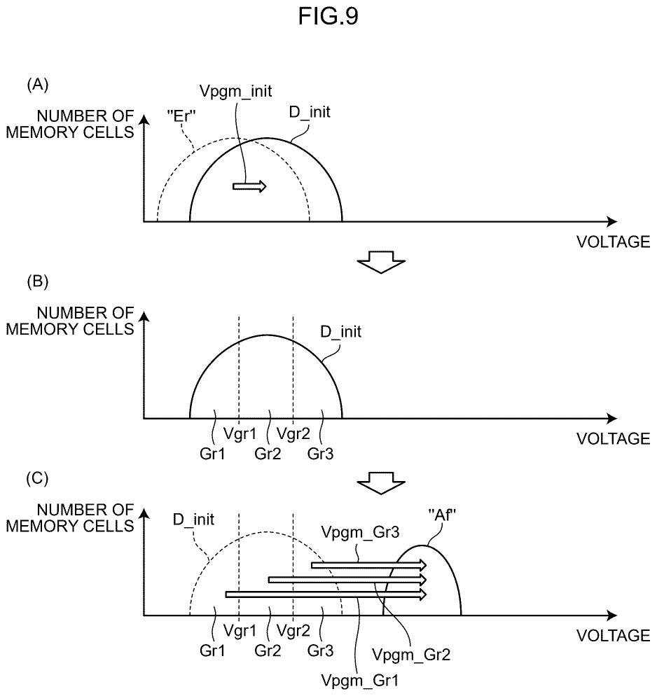

FIG. 9 is a schematic diagram for explaining the first write operation according to the first embodiment.

First, the access circuit 30 selects all memory cells in which the final target state is any of states “A” to “G” (in other words, all memory cells in which the intermediate target state is any of states “Af” to “Gf”) of the memory cell group MCG that is the target of the write operation, and executes a program operation in which one program pulse of a predetermined voltage Vpgm_init is applied to the word line. Accordingly, as illustrated in part (A) of FIG. 9, the threshold value of all memory cells for which the final target state is any of the states “A” to “G” changes to the high voltage side by a uniform amount. This causes the distribution of all memory cells for which the final target state is any of the states “A” to “G” to form a distribution D_int that is slightly shifted from the state “Er” distribution to the high voltage side.

Subsequently, the access circuit 30 groups the memory cells included in the distribution D_int into two or more subgroups according to the threshold voltage by read operation using one or more read levels.

For example, in the example illustrated in part (B) of FIG. 9, voltage Vgr1 and voltage Vgr2 are used as read levels. Based on the result of the read operation for each read level in which voltages Vgr1 and Vgr2 are used as read levels, the access circuit 30 identifies whether the threshold voltage of each memory cell included in the distribution D_int is in a voltage range in which the threshold voltage is smaller than the voltage Vgr1, a voltage range from voltage Vgr1 to voltage Vgr2, or a voltage range in which the threshold voltage is larger than the voltage Vgr2. The access circuit 30 then classifies memory cells for which the threshold voltage is in the voltage range smaller than the voltage Vgr1 into the subgroup Gr1, memory cells for which the threshold voltage is in the voltage range from the voltage Vgr1 to the voltage Vgr2 into the subgroup Gr2, and memory cells for which the threshold voltage is in the voltage range greater than the voltage Vgr2 into the subgroup Gr3.

For further details, the access circuit 30 selects all memory cells in which the final target state is any of the states “A” to “G” and executes a read operation using the voltage Vgr1 as the read level, and a read operation using the voltage Vgr2 as the read level. The access circuit 30 classifies memory cells that are determined to be in a conducting state in a read operation using the voltage Vgr1 as the read level into the subgroup Gr1. The access circuit 30 classifies memory cells that are determined to be in a non-conducting state in a read operation using voltage Vgr1 as the read level, and that are determined to be in a conducting state in a read operation using voltage Vgr2 as the read level, into the subgroup Gr2. The access circuit 30 classifies memory cells that are determined to be in a non-conducting state in a read operation using the voltage Vgr2 as the read level into the subgroup Gr3. This groups each group of memory cells that share a common voltage range in which a threshold is present out of two or more voltage ranges delimited by one or more read levels.

Hereafter, a read operation in which each of one or more read levels is used as a read level to group is referred to as a group read operation.

By the group read operation, each memory cell included in the distribution D_int is classified into one of three subgroups Gr1 to Gr3 with different threshold voltage heights. It should be noted that the sense amplifier circuit 14 executes the determination as to whether the memory cell is in the conducting state or non-conducting state and the classification based on the determination result. The sense amplifier circuit 14 stores the classification results in the data latch circuit 16.

In the example illustrated in FIG. 9, two voltages Vgr1 and Vgr2 were used as read levels in the group read operation. The number of voltages used as read levels in the group read operation is not limited to two. If the number of voltages used as read levels is R (R is an integer greater than or equal to 1), each of all memory cells for which the final target state is any of states “A” to “G” is classified into (R+1) subgroups corresponding to (R+1) voltage ranges delimited by R read levels by the group read operation.

The voltage Vpgm of the program pulse and the amount of change in the threshold voltage are correlated. The higher the voltage Vpgm of the program pulse, the greater the amount of change in the threshold voltage. The lower the voltage Vpgm of the program pulse, the smaller the amount of change in the threshold voltage.

Therefore, for a plurality of memory cells with the same intermediate target state, the access circuit 30 applies one program pulse to the selected word line using a voltage corresponding to the voltage range for each subgroup as the voltage Vpgm. For example, the access circuit 30 uses one program pulse of a voltage for a subgroup of memory cells where the threshold voltage is in the first voltage range. For the subgroup where the threshold voltage is in the second voltage range on the higher side of the first voltage range, the access circuit 30 uses one program pulse with a voltage lower than the voltage of the program pulse used for the subgroup of memory cells for which the threshold voltage is in the first voltage range.

For further details, the access circuit 30 selects a memory cell for each combination of the target state and the subgroup, and executes a program operation for the selected memory cell using a program pulse with a voltage corresponding to the combination of the target state and the subgroup.

For example, as illustrated in part (C) of FIG. 9, the access circuit 30 selects memory cells included in the subgroup Gr1 out of the memory cells for which the final target state is state “A” (in other words, memory cells for which the intermediate target state is state “Af”), and applies a program pulse with voltage Vpgm_Gr1 to the selected word line. The access circuit 30 selects memory cells included in the subgroup Gr2 out of the memory cells for which the final target state is state “A” (in other words, memory cells for which the intermediate target state is state “Af”), and applies a program pulse with voltage Vpgm_Gr2 to the selected word line. The access circuit 30 selects memory cells included in the subgroup Gr3 out of the memory cells for which the final target state is state “A” (in other words, memory cells for which the intermediate target state is state “Af”), and applies a program pulse with voltage Vpgm_Gr3 to the selected word line.

The voltage Vpgm_Gr1 is a voltage that allows the threshold voltage of the memory cells belonging to the subgroup Gr1 to be set to the state “Af” by applying one program pulse. The voltage Vpgm_Gr2 is a voltage that allows the threshold voltage of the memory cells belonging to the subgroup Gr2 to be set to the state “Af” by applying one program pulse. The voltage Vpgm_Gr3 is a voltage that allows the threshold voltage of the memory cells belonging to the subgroup Gr3 to be set to the state “Af” by applying one program pulse. The voltage Vpgm_Gr2 is lower than the voltage Vpgm_Gr1, and the voltage Vpgm_Gr3 is lower than the voltage Vpgm_Gr2.

In this way, by using a higher voltage program pulse for memory cells with a lower threshold voltage out of the memory cells included in the distribution D_int, the voltage width of the threshold voltage distribution in the intermediate target state can be narrower than the voltage width of the distribution D_int.

The access circuit 30 individually selects memory cells for each subgroup, also for memory cells for which the intermediate target state is state “Bf”, memory cells for which the intermediate target state is state “Cf”, memory cells for which the intermediate target state is state “Df”, memory cells for which the intermediate target state is state “Ef”, memory cells for which the intermediate target state is state “Ff”, and memory cells for which the intermediate target state is state “Gf”, in the same manner as for memory cells for which the intermediate target state is state “Af”, and applies a program pulse to the selected word line.

Hereafter, a combination of a certain state “S” (where S is any of A to G) and the subgroup Grx (where x is any of 1 to 3) is referred to as a combination (S, Grx).

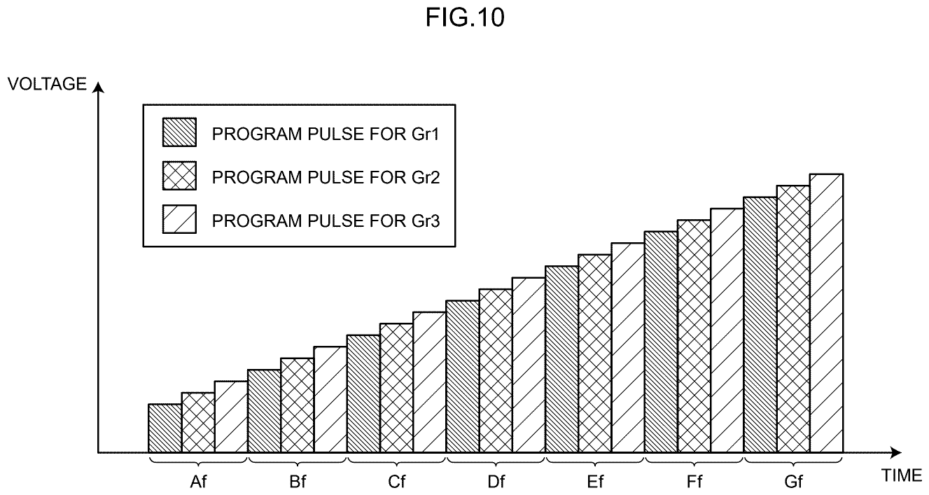

FIG. 10 is a schematic diagram for explaining the voltage of the program pulse applied to the selected word line in the first write operation according to the first embodiment. In this figure, the horizontal axis indicates time and the vertical axis indicates voltage.

In the example illustrated in FIG. 10, all memory cells corresponding to combination (Af, Gr1), all memory cells corresponding to combination (Af, Gr2), all memory cells corresponding to combination (Af, Gr3), all memory cells corresponding to combination (Bf, Gr1), all memory cells corresponding to combination (Bf, Gr2), all memory cells corresponding to combination (Bf, Gr3), all memory cells corresponding to combination (Cf, Gr1), all memory cells corresponding to combination (Cf, Gr2), all memory cells corresponding to combination (Cf, Gr3), all memory cells corresponding to combination (Df, Gr1), all memory cells corresponding to combination (Df, Gr2), all memory cells corresponding to combination (Df, Gr3), all memory cells corresponding to combination (Ef, Gr1), all memory cells corresponding to combination (Ef, Gr2), all memory cells corresponding to combination (Ef, Gr3), all memory cells corresponding to combination (Ff, Gr1), all memory cells corresponding to combination (Ff, Gr2), all memory cells corresponding to combination (Ff, Gr3), all memory cells corresponding to combination (Gf, Gr1), all memory cells corresponding to combination (Gf, Gr2), and combination (Gf, Gr3), are selected in this order, and for each combination of the target state and the subgroup, one program pulse is applied, the voltage of which corresponds to the combination of the target state and the subgroup.

Thus, according to the first embodiment, in the first write operation, one program pulse of voltage Vpgm is first applied, and then the program pulses of the number of combinations of the target states and subgroups except for the state “Er” are applied. In addition, the verify operation can be eliminated. Therefore, compared to the comparative example in which program operations and verify operations are executed repeatedly, it is possible to reduce the time required for the first write operation. As the time required for the first write operation is reduced, the time required for the write operations (that is, the first write operation and the second write operation) is reduced.

It should be noted that the order in which the combination of the intermediate target state and the subgroup is selected is not limited to the order illustrated in FIG. 10.

When a write operation is executed for a plurality of memory cell groups MCG included in one block BLK, the order of the first write operation and the second write operation for the plurality of memory cell groups MCG can be set in various ways. The Pass Write method and Foggy & Fine method are known as the write method in which the order of execution of the first write operation and the second write operation for a plurality of memory cell groups MCG is defined. In the first embodiment, either write method can be applied.

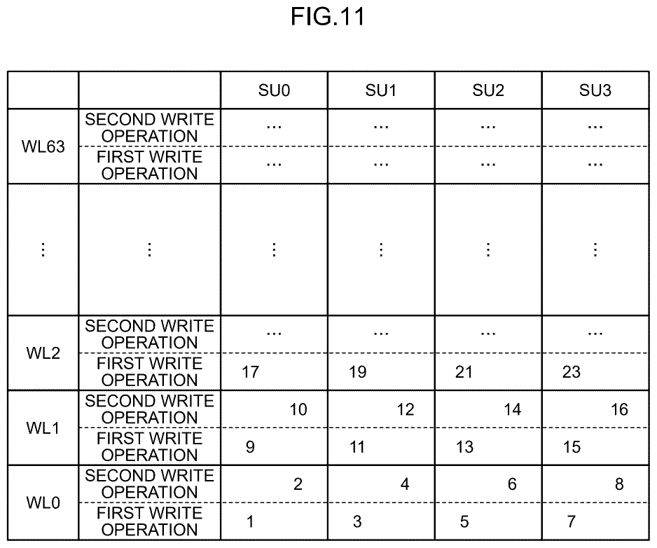

FIG. 11 is a diagram for explaining the Pass Write method according to the first embodiment.

According to the Pass Write method, as the first to second operations, the first operation and the second operation after the first operation are executed for the memory cell group MCG of the string unit SU0 connected to the word line WL0. Next, as the third to fourth operations, the first operation and the second operation after the first operation are executed for the memory cell group MCG of the string unit SU1 connected to the word line WL0. Next, as the fifth to sixth operations, the first write operation and the second write operation after the first write operation are executed for the memory cell group MCG of the string unit SU2 connected to the word line WL0. Next, as the seventh to eighth operations, the first write operation and the second write operation after the first write operation are executed for the memory cell group MCG of the string unit SU3 connected to the word line WL0.

When the first and second write operations for the memory cell group MCG of all the string units SU connected to the word line WL0 are completed, as the ninth to tenth operations, the first write operation and the second write operation after the first write operation are executed for the memory cell group MCG of the string unit SU0 connected to the word line WL1. Next, as the eleventh to twelfth operations, the first write operation and the second write operation after the first write operation are executed for the memory cell group MCG of the string unit SU1 connected to the word line WL1. Next, as the thirteenth to fourteenth operations, the first write operation and the second write operation after the first write operation are executed for the memory cell group MCG of the string unit SU2 connected to the word line WL1. Next, as the fifteenth to sixteenth operations, the first write operation and the second write operation after the first write operation are executed for the memory cell group MCG of the string unit SU3 connected to the word line WL1.

In this way, according to the Pass Write method, the first write operation and the second write operation are executed for the memory cell group MCG connected to a certain word line WLm. After that, the first write operation and the second write operation are executed for the memory cell group MCG connected to the word line WLm+1 adjacent to the word line WLm.

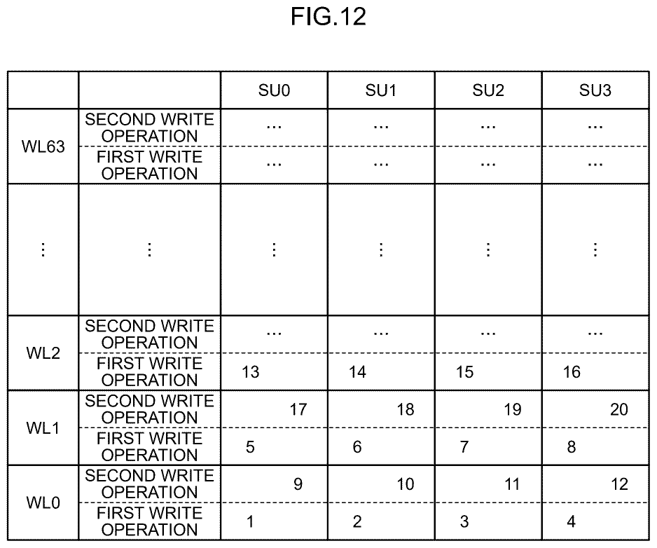

FIG. 12 is a diagram for explaining the Foggy & Fine method according to the first embodiment. In the Foggy & Fine method, the first write operation is also referred to as the Foggy program, and the second write operation is referred to as the Fine program.

According to the Foggy & Fine method, as the first to fourth operations, the first write operation is executed for the memory cell group MCG connected to the word line WL0. Next, as the fifth to eighth operations, the first write operation is executed for the memory cell group MCG connected to the word line WL1.

Next, as the ninth to twelfth operations, the second write operation is executed for the memory cell group MCG connected to the word line WL0. The operations are then repeated in the same execution order. That is, after the first write operation is executed for the memory cell group MCG connected to the word line WLm, the first write operation is executed for the memory cell group MCG connected to the word line WLm+1 before the second write operation for the memory cell group MCG connected to the word line WLm.

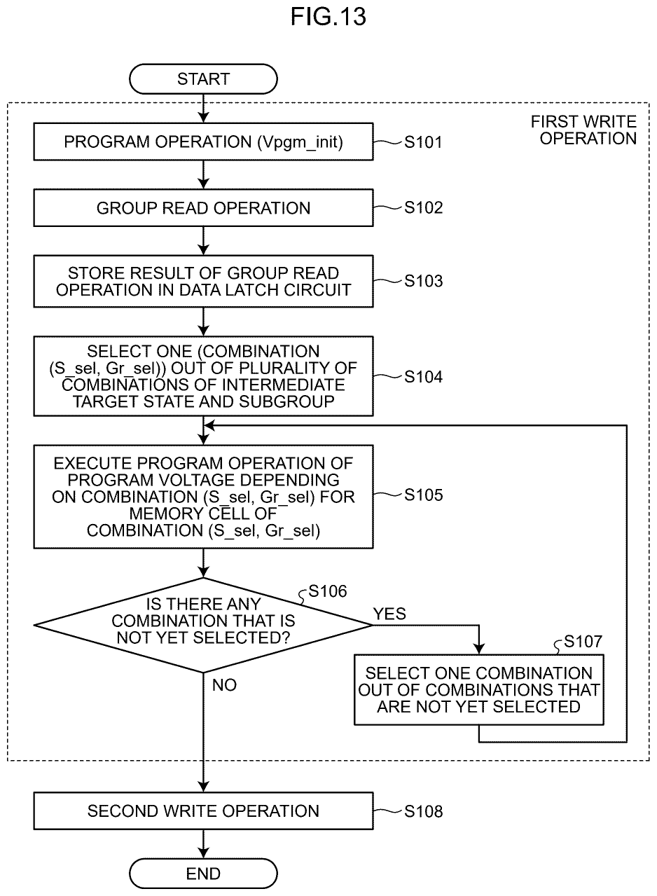

FIG. 13 is a flow chart illustrating an example of a write operation in the memory chip CP according to the first embodiment. Here, the write operation for one memory cell group MCG will be described. In the description of FIG. 13, the one memory cell group MCG is referred to as the target memory cell group MCG.

First, the access circuit 30 executes the first write operation, which makes up steps S101 to S107. In the first write operation, the access circuit 30 executes a program operation using the program voltage Vpgm_init (step S101). The access circuit 30 selects all memory cells of the target memory cell group MCG except for the memory cells for which the final target state is state “Er”, that is, the memory cells for which the final target state is any of state “A” to state “G”, and applies a program pulse of voltage Vpgm_init to the word line WL to which the target memory cell group MCG is connected.

Subsequently, the access circuit 30 executes a group read operation (step S102). According to the example illustrated in FIG. 9 and FIG. 10, the access circuit 30 executes a read operation using voltages Vgr1 and Vgr2 as read levels, respectively. Based on the result of a read operation using voltages Vgr1 and voltage Vgr2 as read levels, the sense amplifier circuit 14 classifies each memory cell in which the final target state is any of state “A” to state “G” into one of subgroup Gr1 where the threshold voltage of the memory cell is in the voltage range smaller than the voltage Vgr1, subgroup Gr2 where the threshold voltage of the memory cell is in the voltage range from voltage Vgr1 to voltage Vgr2, and subgroup Gr3 where the threshold voltage of the memory cell is in the voltage range greater than the voltage Vgr2.

The sense amplifier circuit 14 stores the result of the group read operation, that is, the classification result, in the data latch circuit 16 (step S103).

Subsequently, the access circuit 30 selects one of a plurality of combinations of the intermediate target state and the subgroup (step S104). The combination selected in step S104 is denoted as combination (S_sel, Gr_sel). In step S104, all intermediate target states except the state “Erf” may be selected.

The access circuit 30 executes a program operation using a program voltage corresponding to the combination (S_sel, Gr_sel) for all memory cells corresponding to the combination (S_sel, Gr_sel) (step S105). The access circuit 30 selects all memory cells (S_sel, Gr_sel) corresponding to the combination (S_sel, Gr_sel) out of the target memory cell groups MCG, and applies one program pulse with a program voltage corresponding to the combination (S_sel, Gr_sel) to the word line WL to which the target memory cell group MCG is connected.

If there is a combination that is not yet selected out of a plurality of combinations of the intermediate target states and subgroups (step S106: Yes), the access circuit 30 selects one combination out of the combinations that are not yet selected (step S107). The newly selected combination in step S107 is set as a combination (S_sel, Gr_sel), and the process in step S105 is executed.

If there are no combinations that have not yet been selected out of the plurality of combinations of the intermediate target states and subgroups (step S106: No), the first write operation is completed, and the access circuit 30 executes the second write operation (step S108). The write operation for the target memory cell group MCG is then completed.

In the above description, the target memory cell group MCG is an example of a first plurality of memory cells. The state “Erf” to the state “Gf” are examples of the plurality of first states. The plurality of memory cells in the target memory cell group MCG for which the intermediate target state is any of the states “Af” to “Gf” are examples of the second plurality of memory cells. A certain intermediate target state of the state “Af” to the state “Gf” is an example of a second state. The state “Erf” is an example of a third state. The states “Af” to “Gf” are examples of a plurality of fourth states. The first write operation for the target memory cell group MCG is an example of the first operation. The second write operation for the target memory cell group MCG is an example of the second operation. The word line connected to the target memory cell group MCG is an example of a first word line. A word line adjacent to a word line connected to the target memory cell group MCG is an example of a second word line. The memory cell group MCG connected to a word line adjacent to the word line connected to the target memory cell group MCG is an example of a seventh plurality of memory cells. The first write operation for the memory cell group MCG connected to a word line adjacent to the word line connected to the target memory cell group MCG is an example of the third operation. The voltage Vpgm_init is an example of the first voltage. One or more read levels (for example, voltages Vgr1, Vgr2 illustrated in FIG. 9) used in the group read operation are examples of one or more read levels.

As mentioned above, according to the first embodiment, the access circuit 30 applies a program pulse of the voltage Vpgm_init to the selected word line in the first write operation, thereby uniformly changing the threshold voltage of all memory cells for which the intermediate target states are state “Af” to state “Gf” out of the target memory cell group MCG (for example, see part (A) in FIG. 9, step S101 in FIG. 13). After the application of the program pulse of the voltage Vpgm_init, the access circuit 30 executes a read operation using one or more read levels, that is, a group read operation, for all memory cells out of the target memory cell group MCG, for which the intermediate target state is any of the states “Af” to “Gf”. By the group read operation, the access circuit 30 identifies which of two or more voltage ranges delimited by one or more read levels the threshold voltage of each of the target memory cell groups MCG for which the intermediate target states are state “Af” to state “Gf” lies in (for example, see part (B) in FIG. 9, steps S102 and S103 in FIG. 13). The access circuit 30 executes, for each subgroup, an operation for selecting a subgroup of memory cells that share a common voltage range in which a threshold voltage is present out of the two or more voltage ranges delimited by one or more read levels to apply one program pulse of the voltage corresponding to the voltage range to the selected word line to set the threshold voltage of each memory cell of the one subgroup to an intermediate target state, for the plurality of memory cells for which the intermediate target state is a certain state out of all memory cells for which the intermediate target states are states “Af” to state “Gf” out of the target memory cell group MCG.

Therefore, the time required for the first write operation is reduced compared to the comparative example. As the time required for the first write operation is reduced, the time required for the write operation (that is, the first write operation and the second write operation) is reduced.

In addition, according to the first embodiment, when the access circuit 30 selects a plurality of memory cells included in a subgroup corresponding to a certain voltage range (represented as the first voltage range), it applies one program pulse of the voltage corresponding to the first voltage range to the selected word line. When the access circuit 30 selects a plurality of memory cells included in a subgroup corresponding to another voltage range (represented as the second voltage range) on the side of the voltage higher than the first voltage range, the access circuit 30 applies one program pulse with a voltage lower than the voltage of the program pulse when the first voltage range is selected for the selected word line.

Therefore, it is possible to make the threshold voltage width of the distribution of the target state smaller than the threshold voltage width of the distribution D_init without repeating the program operation and the verify operation. Since the verify operation for each program operation can be eliminated, the time required for the first write operation is shortened compared to the comparative example.

In addition, according to the first embodiment, in the first write operation, the access circuit 30 selects all memory cells of one combination for each combination of the intermediate target state of the threshold voltage and the voltage range in which the threshold voltage is present, and applies one program pulse of the voltage corresponding to the one combination to the selected word line, thereby setting the threshold voltage of all memory cells corresponding to each combination to the intermediate target state.

Therefore, the access circuit 30 can set the threshold voltage of each memory cell included in the target memory cell group MCG to the intermediate target state.

It should be noted that in the explanation mentioned above, memory cells for which the intermediate target state is any of states except “Erf”, which is the state at the lowest voltage, out of the states “Erf” to “Gf”, are targeted for the program operation using the program pulse of voltage Vprg_init. Since the amount of change in the threshold voltage due to the program pulse of the voltage Vprg_init is small, all memory cells included in the target memory cell group MCG may be targeted to program operation using the program pulse of the voltage Vprg_init, regardless of the intermediate target state.

In addition, according to the first embodiment, when the Pass Write method is applied, the access circuit 30 executes the first write operation and the second write operation for a certain memory cell group MCG, and then executes the first write operation for a memory cell group MCG adjacent to the certain memory cell group MCG.

In addition, according to the first embodiment, when the Foggy & Fine method is applied, the access circuit 30 executes the first write operation for a certain memory cell group MCG (represented as the first memory cell group MCG), and then executes the first write operation for another memory cell group MCG (represented as the second memory cell group MCG) adjacent to the first memory cell group MCG. After executing the first write operation for the second memory cell group MCG, the access circuit 30 executes the second write operation for the first memory cell group MCG.

### Second Embodiment

In the program operation explained in the first embodiment, as already explained, a “L” level (for example, ground voltage Vss, 0 V) is applied to the bit line BL that corresponds to the memory cell for which the threshold voltage is to be increased (where “0” data is given) and a “H” level (for example, 2.5 V) is applied to the bit line BL that corresponds to the memory cell for which the threshold voltage is not to be increased (where “1” data is given). In this case, only two types of control can be executed: the threshold voltage is increased or maintained for a plurality of memory cells included in the memory cell group MCG.

On the other hand, in the second embodiment, the access circuit 30 is configured to be able to execute a quick pass write (QPW) operation as a program operation.

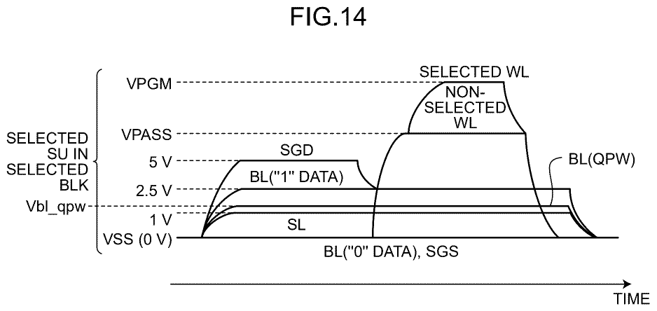

FIG. 14 is a diagram illustrating potential changes of each wiring during QPW operation according to the second embodiment.

In the QPW operation, as illustrated in FIG. 14, a voltage higher than the “L” level (ground voltage Vss, for example 0 V) and lower than the “H” level (write inhibit voltage Vinhibit, for example 2.5 V) is applied to the bit line BL corresponding to the memory cell for which the threshold voltage is to be increased with a small change width. That is, the charging level of the bit line BL is increased compared to the bit line BL corresponding to the memory cell for which the threshold voltage is to be increased (where “0” data is given). Accordingly, in the memory cell of interest, the channel potential Vch rises above the “L” level (ground voltage Vss, for example, 0 V). Therefore, the injection of electrons into the charge accumulation film due to the program voltage Vpgm applied to the selected word line is reduced by the amount of increase in the channel voltage Vch. Therefore, in the QPW operation, three types of control can be executed for a plurality of memory cells included in the memory cell group MCG: the threshold voltage is increased, the threshold voltage is maintained, or the threshold voltage is increased with a small change width. Hereinafter, the voltage applied to the bit line BL for this QPW operation will be referred to as the QPW voltage Vbl_qpw.

The access circuit 30 simultaneously selects all memory cells corresponding to the first combination, out of a plurality of combinations of the intermediate target state of the threshold voltage and a voltage range in which the threshold voltage is present, and all memory cells corresponding to the second combination that is different from the first combination, and applies one program pulse of a predetermined voltage to the selected word line. Here, the access circuit 30 executes the QPW operations for one of all memory cells corresponding to the first combination and all memory cells corresponding to the second combination, and the normal program operations mentioned in the first embodiment for the other thereof. That is, the access circuit 30 applies one program pulse with a predetermined voltage to the selected word line, while applying a QPW voltage Vbl_qpw to each bit line connected to one of all memory cells corresponding to the first combination and all memory cells of the second combination, and applying a ground voltage Vss (for example, 0 V) to each bit line connected to the other of all memory cells corresponding to the first combination and all memory cells corresponding to the second combination. This allows the threshold voltage of each of the two different combinations of memory cells to be set in the intermediate target state with one program pulse.

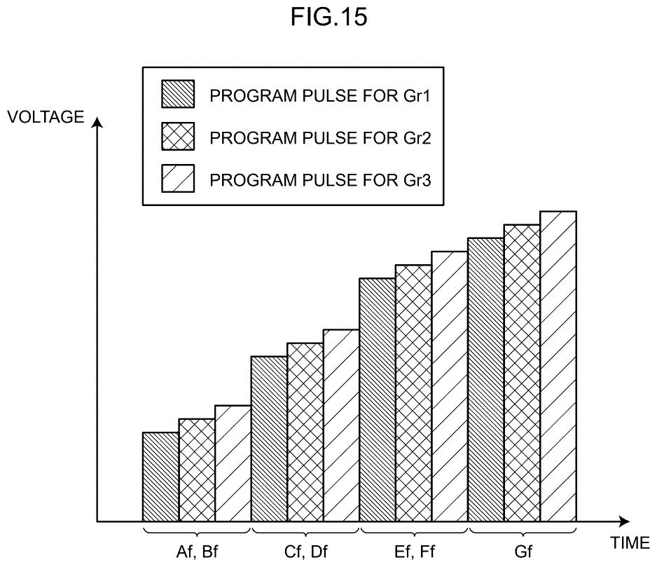

FIG. 15 is a schematic diagram for explaining the voltage of the program pulse applied to the selected word line in the first write operation according to the second embodiment.

In the example illustrated in FIG. 15, a program operation using one program pulse is executed simultaneously for all memory cells corresponding to combination (Af, Gr1) and all memory cells corresponding to combination (Bf, Gr1), a program operation using one program pulse is executed simultaneously for all memory cells corresponding to combination (Af, Gr2) and all memory cells corresponding to combination (Bf, Gr2), and a program operation using one program pulse is executed simultaneously for all memory cells corresponding to combination (Af, Gr3) and all memory cells corresponding to combination (Bf, Gr3). Here, the program operation for each memory cell corresponding to the combination (Bf, Gr1), the program operation for each memory cell corresponding to the combination (Bf, Gr2), and the program operation for each memory cell corresponding to the combination (Bf, Gr3) are normal program operations. The program operation for each memory cell corresponding to the combination (Af, Gr1), the program operation for each memory cell corresponding to the combination (Af, Gr2), and the program operation for each memory cell corresponding to the combination (Af, Gr3) are QPW operations.

A program operation using one program pulse is executed simultaneously for all memory cells corresponding to the combination (Cf, Gr1) and all memory cells corresponding to the combination (Df, Gr1), a program operation using one program pulse is executed simultaneously for all memory cells corresponding to the combination (Cf, Gr2) and all memory cells corresponding to the combination (Df, Gr2), and a program operation using one program pulse is executed simultaneously for all memory cells corresponding to the combination (Cf, Gr3) and all memory cells corresponding to the combination (Df, Gr3). Here, the program operation for each memory cell corresponding to the combination (Df, Gr1), the program operation for each memory cell corresponding to the combination (Df, Gr2), and the program operation for each memory cell corresponding to the combination (Df, Gr3) are normal program operations. The program operation for each memory cell corresponding to the combination (Cf, Gr1), the program operation for each memory cell corresponding to the combination (Cf, Gr2), and the program operation for each memory cell corresponding to the combination (Cf, Gr3) are QPW operations.

A program operation using one program pulse is executed simultaneously for all memory cells corresponding to the combination (Ef, Gr1) and all memory cells corresponding to the combination (Ff, Gr1), and a program operation using one program pulse is executed simultaneously for all memory cells corresponding to the combination (Ef, Gr2) and all memory cells corresponding to the combination (Ff, Gr2), and a program operation using one program pulse is executed simultaneously for all memory cells corresponding to the combination (Ef, Gr3) and all memory cells corresponding to the combination (Ff, Gr3). Here, the program operation for each memory cell corresponding to the combination (Ff, Gr1), the program operation for each memory cell corresponding to the combination (Ff, Gr2), and the program operation for each memory cell corresponding to the combination (Ff, Gr3) are normal program operations. The program operation for each memory cell corresponding to the combination (Ef, Gr1), the program operation for each memory cell corresponding to the combination (Ef, Gr2), and the program operation for each memory cell corresponding to the combination (Ef, Gr3) are QPW operations.

Thus, according to the second embodiment, by applying one program pulse to the selected word line by different voltages applied to the bit lines connected to the memory cells corresponding to each combination, it is possible to set the threshold voltages of the memory cells corresponding to the two different combinations in the intermediate target state at the same time. As a result, the number of program operations required for the first write operation is further reduced, and the time required for the write operation is further reduced.

In the first and second embodiments, the memory chip CP is configured to execute the write operation divided into a first write operation and a second write operation, and the program operation is executed for each combination of the target state and the subgroup in the first write operation. The technique for the program operation for each combination of the target state and the subgroup mentioned in the first and second embodiments can be applied regardless of the number of stages in which write operation is divided. In addition, the technique for the program operation for each combination of the target state and the subgroup mentioned in the first and second embodiments can be applied to any stage.

According to the first and second embodiments, the semiconductor memory device includes: a first plurality of memory cells, a gate of each of the first plurality of memory cells being connected to a first word line; and a circuit that executes a first operation of setting a threshold voltage of each of the first plurality of memory cells to a first state corresponding to data out of a plurality of first states. In the first operation, the circuit causes a threshold voltage of each of a second plurality of memory cells out of the first plurality of memory cells to change by a uniform amount by applying a program pulse of a first voltage to the first word line. Then, after applying the program pulse of the first voltage, by executing a read operation using one or more read levels different from each other for the second plurality of memory cells, the circuit identifies which of two or more voltage ranges delimited by the one or more read levels the threshold voltage of each of the second plurality of memory cells is in. The circuit then sets a threshold voltage of a third plurality of memory cells to the second state by executing, to the third plurality of memory cells having a setting destination of the threshold voltage in a second state, which is one of the plurality of first states, out of the second plurality of memory cells, an operation of selecting a plurality of memory cells included in one group and applying one program pulse of a voltage according to a voltage range corresponding to one group to the first word line for each group of memory cells that share a common voltage range in which a threshold voltage is present out of the two or more voltage ranges.

Therefore, it is possible to obtain a semiconductor memory device that requires a short time for the write operation, that is, a short time for storing data.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a first plurality of memory cells, a gate of each of the first plurality of memory cells being connected to a first word line; and
a circuit that executes a first operation of setting a threshold voltage of each of the first plurality of memory cells to a first state corresponding to data out of a plurality of first states, wherein the first operation includes:
causing a threshold voltage of each of a second plurality of memory cells out of the first plurality of memory cells to change by a uniform amount by applying a program pulse of a first voltage to the first word line,
after applying the program pulse of the first voltage, by executing a read operation using one or more read levels for the second plurality of memory cells, identifying which of two or more voltage ranges the threshold voltage of each of the second plurality of memory cells is in, the one or more read levels being different from each other, the two or more voltage ranges being delimited by the one or more read levels, and
by executing, to a third plurality of memory cells having a setting destination of the threshold voltage in a second state, which is one of the plurality of first states, out of the second plurality of memory cells, an operation of selecting a plurality of memory cells included in one group and applying one program pulse of a voltage according to a voltage range corresponding to the one group to the first word line for each group of memory cells that share a common voltage range in which a threshold voltage is present out of the two or more voltage ranges, setting a threshold voltage of the third plurality of memory cells to the second state.

2. The semiconductor memory device according to claim 1 wherein
the circuit:
applies one program pulse of a second voltage to the first word line when selecting a plurality of memory cells included in a group corresponding to a first voltage range out of the two or more voltage ranges out of the third plurality of memory cells; and
applies one program pulse of a third voltage lower than the second voltage to the first word line when selecting a plurality of memory cells included in a group corresponding to a second voltage range out of the two or more voltage ranges out of the third plurality of memory cells, the second voltage range being at a higher voltage than the first voltage range.

3. The semiconductor memory device according to claim 1, wherein
the circuit, in the first operation, for each combination of a state of a setting destination of a threshold voltage and a voltage range in which the threshold voltage is present,
sets the threshold voltage of each of a fourth plurality of memory cells to the state of the setting destination by selecting the fourth plurality of memory cells corresponding to the combination out of the second plurality of memory cells and applying one program pulse of a voltage corresponding to the combination to the first word line.

4. The semiconductor memory device according to claim 1, wherein
the first plurality of memory cells are connected to bit lines that are different from each other, and
the circuit, in the first operation,
sets a threshold voltage of each of a fifth plurality of memory cells and a sixth plurality of memory cells to a state of the setting destination by applying one program pulse to the first word line in a state in which the fifth plurality of memory cells and the sixth plurality of memory cells are selected, a fourth voltage is applied to a bit line connected to each of the fifth plurality of memory cells, and a fifth voltage different from the fourth voltage is applied to a bit line connected to the sixth plurality of memory cells, the fifth plurality of memory cells corresponding to a first combination of a state of a setting destination of a threshold voltage and a voltage range in which the threshold voltage is present out of the second plurality of memory cells, the sixth plurality of memory cells corresponding to a second combination different from the first combination out of the second plurality of memory cells.

5. The semiconductor memory device according to claim 1, wherein
the plurality of first states include a third state at a lowest voltage and a plurality of fourth states that differ from the third state, and a state of the setting destination of the threshold voltage in each of the second plurality of memory cells is one of the plurality of fourth states.

6. The semiconductor memory device according to claim 1, wherein
after the first operation, the circuit executes a second operation of setting each of the first plurality of memory cells to a fourth state corresponding to data out of a plurality of fourth states having a smaller distribution width of threshold voltages than a distribution width of threshold voltages in one of the plurality of first states.

7. The semiconductor memory device according to claim 2, wherein
after the first operation, the circuit executes a second operation of setting each of the first plurality of memory cells to a fourth state corresponding to data out of a plurality of fourth states having a smaller distribution width of threshold voltages than a distribution width of threshold voltages in one of the plurality of first states.

8. The semiconductor memory device according to claim 3, wherein
after the first operation, the circuit executes a second operation of setting each of the first plurality of memory cells to a fourth state corresponding to data out of a plurality of fourth states having a smaller distribution width of threshold voltages than a distribution width of threshold voltages in one of the plurality of first states.

9. The semiconductor memory device according to claim 6, further comprising:
a seventh plurality of memory cells, a gate of each of the seventh plurality of memory cells being connected to a second word line adjacent to the first word line, wherein
after executing the first operation and the second operation, the circuit executes a third operation of setting a threshold voltage of each of the seventh plurality of memory cells to a first state corresponding to data out of the plurality of first states.

10. The semiconductor memory device according to claim 6, further comprising:
a seventh plurality of memory cells, a gate of each of the seventh plurality of memory cells being connected to a second word line adjacent to the first word line, wherein the circuit:
executes, after executing the first operation, a third operation of setting a threshold voltage of each of the seventh plurality of memory cells to a first state corresponding to data out of the plurality of first states; and
executes, after executing the third operation, the second operation.

11. A method for storing data in a semiconductor memory device, the method comprising:
executing a first operation of setting a threshold voltage of each of a first plurality of memory cells to a first state corresponding to data out of a plurality of first states, a gate of each of the first plurality of memory cells being connected to a first word line, wherein the first operation includes:
causing a threshold voltage of each of a second plurality of memory cells out of the first plurality of memory cells to change by a uniform amount by applying a program pulse of a first voltage to the first word line,
after applying the program pulse of the first voltage, by executing a read operation using one or more read levels for the second plurality of memory cells, identifying which of two or more voltage ranges the threshold voltage of each of the second plurality of memory cells is in, the one or more read levels being different from each other, the two or more voltage ranges being delimited by the one or more read levels, and
by executing, to a third plurality of memory cells having a setting destination of the threshold voltage in a second state, which is one of the plurality of first states, out of the second plurality of memory cells, an operation of selecting a plurality of memory cells included in one group and applying one program pulse of a voltage according to a voltage range corresponding to the one group to the first word line for each group of memory cells that share a common voltage range in which a threshold voltage is present out of the two or more voltage ranges, setting a threshold voltage of the third plurality of memory cells to the second state.

12. The method for storing data according to claim 11, the method comprising:
applying one program pulse of a second voltage to the first word line in response to selecting a plurality of memory cells included in a group corresponding to a first voltage range out of the two or more voltage ranges out of the third plurality of memory cells, and
applying one program pulse of a third voltage lower than the second voltage to the first word line in response to selecting a plurality of memory cells included in a group corresponding to a second voltage range out of the two or more voltage ranges out of the third plurality of memory cells, the second voltage range being at a higher voltage than the first voltage range.

13. The method for storing data according to claim 11, wherein
the first operation includes, for each combination of a state of a setting destination of a threshold voltage and a voltage range in which the threshold voltage is present,
setting the threshold voltage of each of a fourth plurality of memory cells to the state of the setting destination by selecting the fourth plurality of memory cells corresponding to the combination out of the second plurality of memory cells and applying one program pulse of a voltage corresponding to the combination to the first word line.

14. The method for storing data according to claim 11, wherein
the first plurality of memory cells are connected to bit lines that are different from each other, and
the first operation includes
setting a threshold voltage of each of a fifth plurality of memory cells and a sixth plurality of memory cells to a state of the setting destination by applying one program pulse to the first word line in a state in which the fifth plurality of memory cells and the sixth plurality of memory cells are selected, a fourth voltage is applied to a bit line connected to each of the fifth plurality of memory cells, and a fifth voltage different from the fourth voltage is applied to a bit line connected to the sixth plurality of memory cells, the fifth plurality of memory cells corresponding to a first combination of a state of a setting destination of a threshold voltage and a voltage range in which the threshold voltage is present out of the second plurality of memory cells, the sixth plurality of memory cells corresponding to a second combination different from the first combination out of the second plurality of memory cells,
.

15. The method for storing data according to claim 11, wherein
the plurality of first states include a third state at a lowest voltage and a plurality of fourth states that differ from the third state, and a state of the setting destination of the threshold voltage in each of the second plurality of memory cells is one of the plurality of fourth states.

16. The method for storing data according to claim 11, the method further comprising:
after the first operation, executing a second operation of setting each of the first plurality of memory cells to a fourth state corresponding to data out of a plurality of fourth states having a smaller distribution width of threshold voltages than a distribution width of threshold voltages in one of the plurality of first states.

17. The method for storing data according to claim 12, the method further comprising:
after the first operation, executing a second operation of setting each of the first plurality of memory cells to a fourth state corresponding to data out of a plurality of fourth states having a smaller distribution width of threshold voltages than a distribution width of threshold voltages in one of the plurality of first states.

18. The method for storing data according to claim 13, the method further comprising:
after the first operation, executing a second operation of setting each of the first plurality of memory cells to a fourth state corresponding to data out of a plurality of fourth states having a smaller distribution width of threshold voltages than a distribution width of threshold voltages in one of the plurality of first states.

19. The method for storing data according to claim 16, the method further comprising:
after executing the first operation and the second operation, executing a third operation of setting a threshold voltage of each of a seventh plurality of memory cells to a first state corresponding to data out of the plurality of first states, a gate of each of the seventh plurality of memory cells being connected to a second word line adjacent to the first word line.

20. The method for storing data according to claim 16, the method comprising:
after executing the first operation, executing a third operation of setting a threshold voltage of each of a seventh plurality of memory cells to a first state corresponding to data out of the plurality of first states, a gate of each of the seventh plurality of memory cells being connected to a second word line adjacent to the first word line; and
after executing the third operation, executing the second operation.
